(19) United States
(12) Patent Application Publication
(10) Pub. No.: US 2025/0364404 A1
(43) Pub. Date: Nov. 27, 2025

(54) SEMICONDUCTOR DEVICE

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 19/296,601

(22) Filed: Aug. 11, 2025

Related U.S. Application Data
(63) Continuation of application No. PCT/JP2024/005655, filed on Feb. 19, 2024.

(30) Foreign Application Priority Data
Feb. 21, 2023 (JP) 2023-025220

(51) Int. Cl. H01L 23/522; H01L 23/31

(52) U.S. Cl. CPC H01L 23/5227; H01L 23/3192; H01L 23/5223

(57) ABSTRACT

A semiconductor device includes a semiconductor element, a first resin portion, a second conductor, and a second resin portion. The semiconductor element includes a first element surface and a second element surface facing in opposite directions in a thickness-wise direction, element side surfaces, an element insulation layer, and a first conductor. The first resin portion includes a first resin surface and covers the first element surface. The second resin portion includes a second conductor and a second resin surface and covers the first resin surface and the second conductor. The first conductor and the second conductor are located at opposite sides of the element insulation layer and the first resin portion and are opposed to each other in the thickness-wise direction. At least one of the element side surfaces is exposed without being covered by the first resin portion and the second resin portion.

### CROSS-REFERENCE TO RELATED APPLICATIONS

This application is a continuation of, and claims the benefit of priority from International Application No. PCT/JP2024/005655, filed on Feb. 19, 2024, which claims the benefit of priority from Japanese Patent Application No. 2023-025220, filed on Feb. 21, 2023, the entire contents of each are incorporated herein by reference.

### BACKGROUND

The present disclosure relates to a semiconductor device.

A conventional semiconductor device includes a transformer used as an isolation element in transmission of signals and power. Japanese Laid-Open Patent Publication No. 2018-78169 discloses an example of a transformer including two coils opposed to each other in a vertical direction.

### BRIEF DESCRIPTION OF THE DRAWINGS

FIG. 1 is a schematic circuit diagram showing a structure of a signal transmission device.

FIG. 2 is a schematic perspective view of the signal transmission device shown in FIG. 1.

FIG. 3 is a schematic perspective view of the semiconductor device shown in FIG. 2.

FIG. 4 is a schematic perspective view of the semiconductor device shown in FIG. 3 as viewed in a different direction.

FIG. 5 is a schematic plan view showing the structure of the semiconductor device shown in FIG. 3.

FIG. 6 is a schematic plan view showing the structure of the semiconductor device shown in FIG. 5 related to a first coil.

FIG. 7 is a schematic plan view showing the structure of the semiconductor device shown in FIG. 5 related to a second coil.

FIG. 8 is a schematic cross-sectional view taken along line 8-8 in FIG. 5.

FIG. 9 is a schematic cross-sectional view taken along line 9-9 in FIG. 5.

FIG. 10 is a schematic cross-sectional view showing an example of a manufacturing step of a semiconductor device.

FIG. 11 is a schematic plan view showing a modified example of a semiconductor device.

FIG. 12 is a schematic cross-sectional view showing a modified example of a semiconductor device.

FIG. 13 is a schematic cross-sectional view showing a modified example of a semiconductor device.

### DETAILED DESCRIPTION

Embodiments of a semiconductor device in accordance with the present disclosure will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

The following detailed description includes exemplary embodiments of a device, a system, and a method according to the present disclosure. The detailed description is illustrative and is not intended to limit embodiments of the present disclosure or the application and use of the embodiments.

In this specification, the phrase “at least one of” as used in this disclosure means “one or more” of a desired choice. As an example, the phrase “at least one” as used in this description means “only one of the options” or “both of the two options” if the number of options is two. In another example, the phrase “at least one of” as used in this description means “only one single option” or “any combination of two or more options” if the number of options is three or more.

### Schematic Structure of Signal Transmission Device

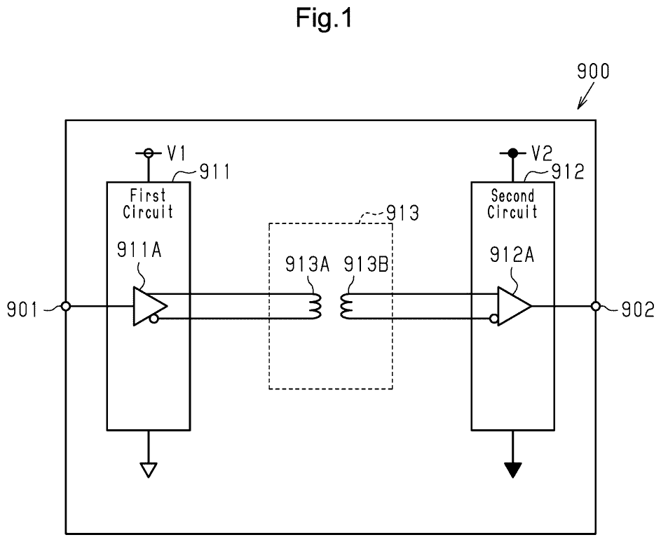

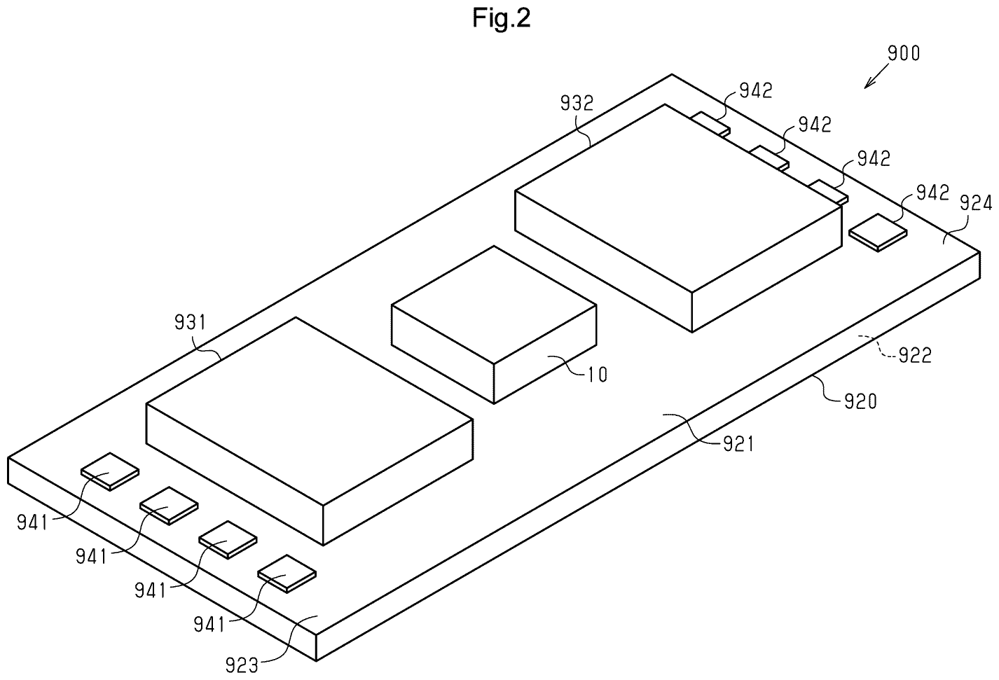

The schematic structure of a signal transmission device 900 will now be described with reference to FIGS. 1 and 2. FIG. 1 is a simplified diagram showing an example of the circuit configuration of the signal transmission device 900. FIG. 2 is a schematic perspective view of the signal transmission device 900.

As shown in FIG. 1, the signal transmission device 900 is configured to transmit a pulse signal while electrically insulating a first terminal 901 and a second terminal 902. The signal transmission device 900 is, for example, a digital isolator. The signal transmission device 900 includes a first circuit 911 electrically connected to the first terminal 901, a second circuit 912 electrically connected to the second terminal 902, and a transformer 913 electrically insulating the first circuit 911 and the second circuit 912.

The first circuit 911 is configured to be activated by the application of a first voltage V1. The first circuit 911 is, for example, electrically connected to an external controller (not shown). The first circuit 911 includes a transmission circuit 911A. The second circuit 912 is configured to be activated by the application of a second voltage V2 that differs from the first voltage V1. The second voltage V2 is, for example, greater than the first voltage V1. The first voltage V1 and the second voltage V2 are direct current voltages. The second circuit 912 is, for example, electrically connected to a drive circuit that is a subject controlled by the controller. An example of the drive circuit is a switching circuit. The second circuit 912 includes a reception circuit 912A. The ground of the first circuit 911 is independent of the ground of the second circuit 912.

The transformer 913 is connected between the transmission circuit 911A and the reception circuit 912A. The transformer 913 includes two coils 913A and 913B. The coil 913A is connected to the transmission circuit 911A. The coil 913B is connected to the reception circuit 912A.

In an example, the controller inputs a control signal into the transmission circuit 911A of the first circuit 911 through the first terminal 901. The reception circuit 912A of the second circuit 912 receives the control signal from the transmission circuit 911A of the first circuit 911 through the transformer 913. The signal transmitted to the second circuit 912 is output from the second circuit 912 to the drive circuit through the second terminal 902. The first terminal 901 may be referred to as an input terminal that inputs a signal into the signal transmission device 900. The second terminal 902 may be referred to as an output terminal that outputs a signal from the signal transmission device 900.

As described above, in the signal transmission device 900, the transformer 913 electrically insulates the first circuit 911 and the second circuit 912. More specifically the transformer 913 restricts transmission of DC voltage between the first circuit 911 and the second circuit 912. While restricting the transmission of DC voltage between the first circuit 911 and the second circuit 912, the transformer 913 allows transmission of pulse signals.

A state in which the first circuit 911 is insulated from the second circuit 912 refers to a state in which transmission of DC voltage between the first circuit 911 and the second circuit 912 is blocked, while transmission of a pulse signal from the first circuit 911 to the second circuit 912 is allowed. Thus, the second circuit 912 is configured to receive a signal from the first circuit 911.

As shown in FIG. 2, the signal transmission device 900 includes a substrate 920 and semiconductor devices 931, 932, and 10.

The substrate 920 has the form of, for example, a rectangular plate. The substrate 920 includes a substrate front surface 921 and a substrate back surface 922 facing in opposite directions. The substrate front surface 921 and the substrate back surface 922 are, for example, rectangular.

First terminals 941 and second terminals 942 are formed on the substrate front surface 921. The first terminals 941 and the second terminals 942 are formed from a material including, for example, copper (Cu). The first terminals 941 are arranged on a first end 923 of the substrate 920. The second terminals 942 are arranged on a second end 924 of the substrate 920 opposite from the first end 923.

The first terminals 941 include a power terminal configured to supply the first voltage V1 shown in FIG. 1, a ground terminal connected to the ground of the first circuit 911, and the first terminal 901. The second terminals 942 include a power terminal configured to supply the second voltage V2 shown in FIG. 1, a ground terminal connected to the ground of the second circuit 912, and the second terminal 902.

The semiconductor devices 931, 932, and 10 are mounted on the substrate front surface 921 of the substrate 920. In an example, the semiconductor devices 931, 932, and 10 are connected to pads (not shown) formed on the substrate front surface 921. The pads are connected to the first terminals 941 and the second terminals 942 by interconnects (not shown). The substrate 920 is formed of, for example, a semiconductor substrate, an insulating substrate formed from a material including epoxy resin, an insulating substrate formed from a material including glass, or an insulating substrate formed from a material including ceramics such as alumina.

The semiconductor device 931 includes the first circuit 911 shown in FIG. 1. The semiconductor device 932 includes the second circuit 912 shown in FIG. 1 The semiconductor device 10 includes the transformer 913 shown in FIG. 1. The semiconductor devices 931, 932, and 10 may each be referred to as a semiconductor chip. The signal transmission device 900 may be referred to as a semiconductor module. The signal transmission device 900 may be referred to as a multi-chip module including multiple semiconductor chips.

The semiconductor device 10 including the transformer 913 may be referred to as an isolation chip disposed between the semiconductor device 931 including the first circuit 911 and the semiconductor device 932 including the second circuit 912 to insulate the semiconductor device 931 from the semiconductor device 932. The semiconductor devices 931, 932, and 10 are arranged in the order of the semiconductor device 931 including the first circuit 911, the semiconductor device 10 including the transformer 913, and the semiconductor device 932 including the second circuit 912 in a direction from the first terminals 941 toward the second terminals 942.

The signal transmission device 900 may include an encapsulation member encapsulating the semiconductor devices 931, 932, and 10 mounted on the substrate front surface 921. In an example, the encapsulation member may be a case accommodating the substrate 920 and the semiconductor devices 931, 932, and 10. The case may be filled with a resin such as silicone resin. In another example, the encapsulation member may be an encapsulation resin covering at least the semiconductor devices 931, 932, and 10. The encapsulation resin may be, for example, a molding resin including an epoxy resin.

### Semiconductor Device Including Transformer

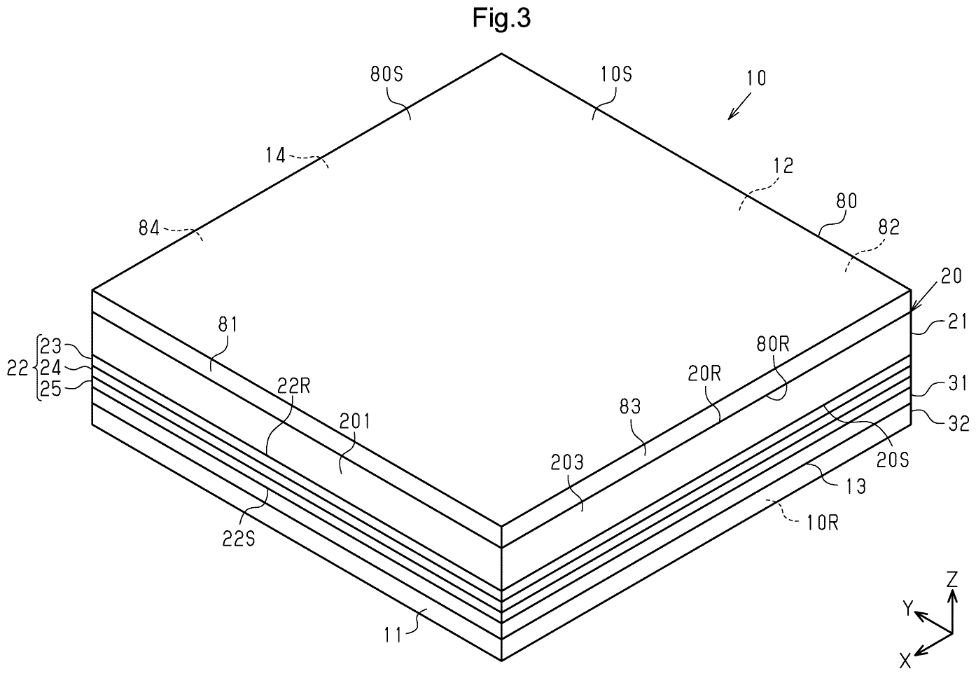

The structure of the semiconductor device 10 will be described with reference to FIGS. 3 to 9.

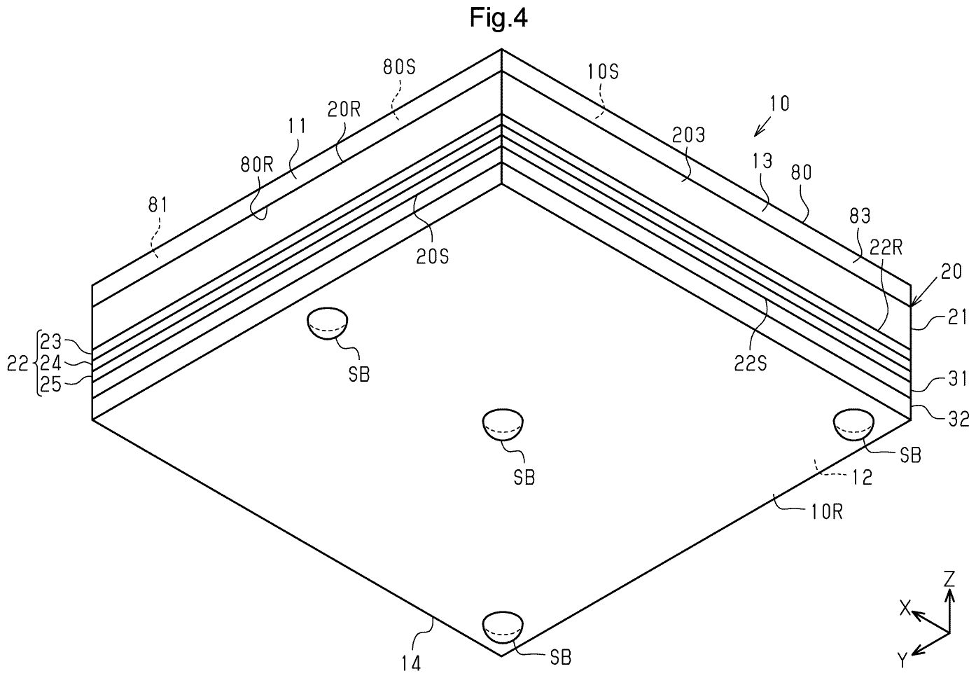

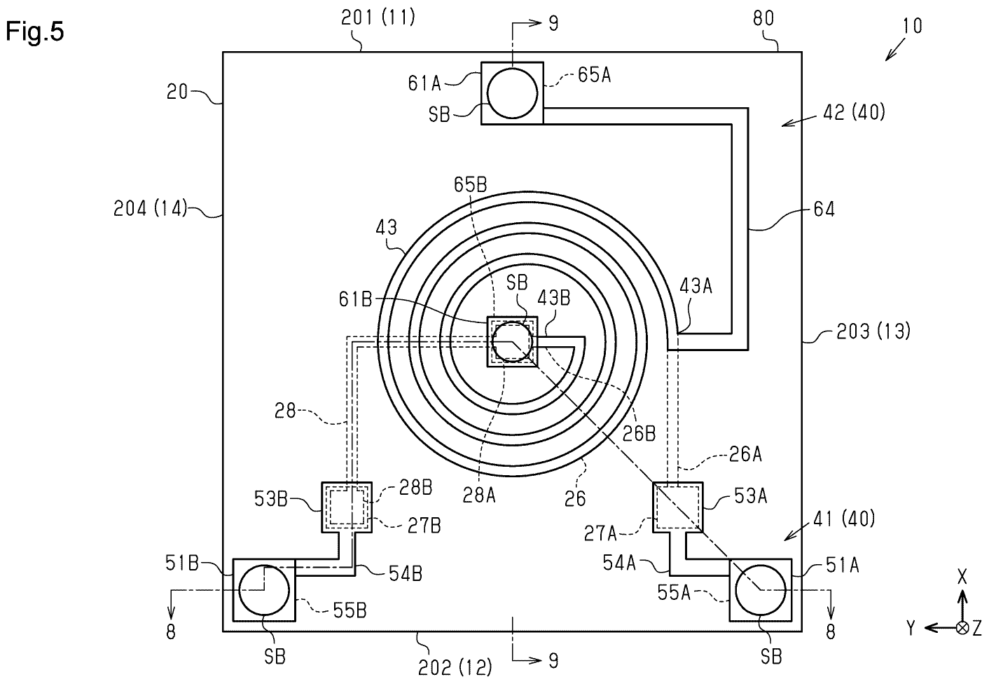

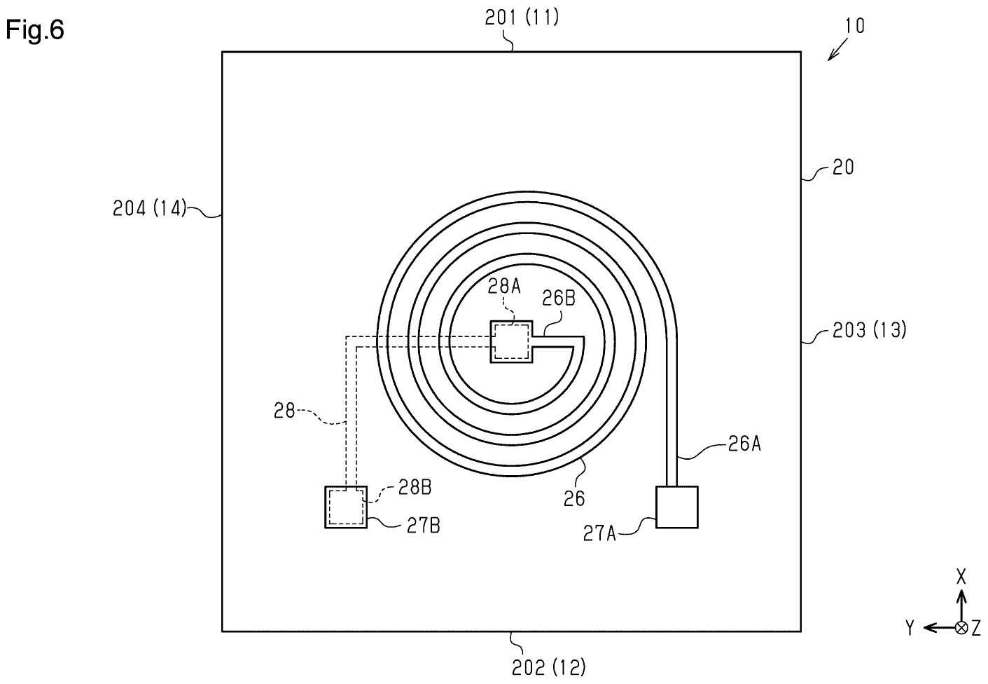

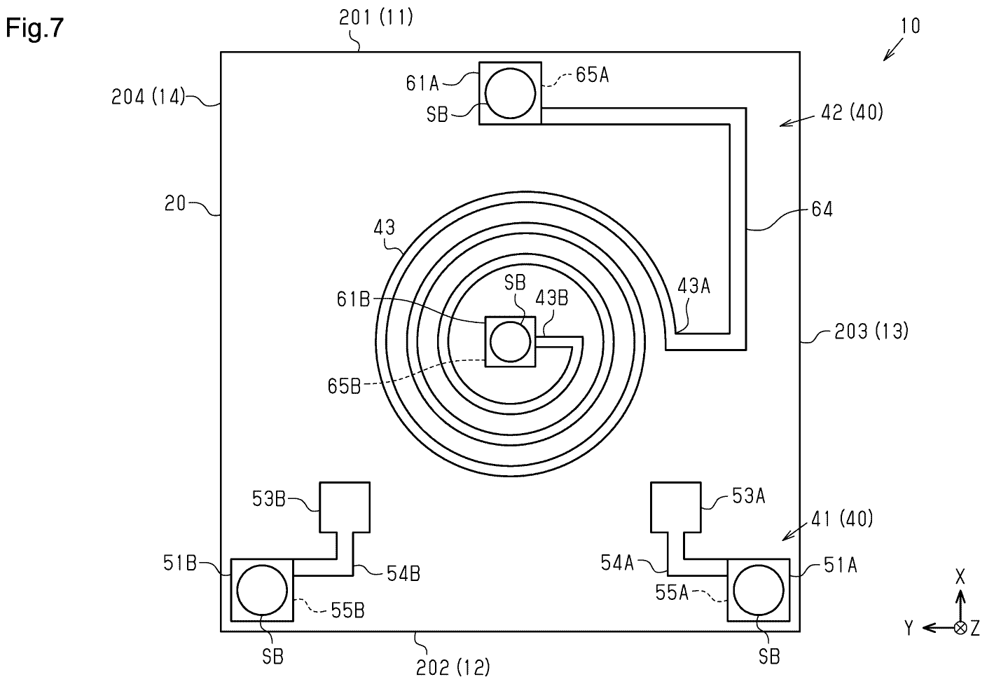

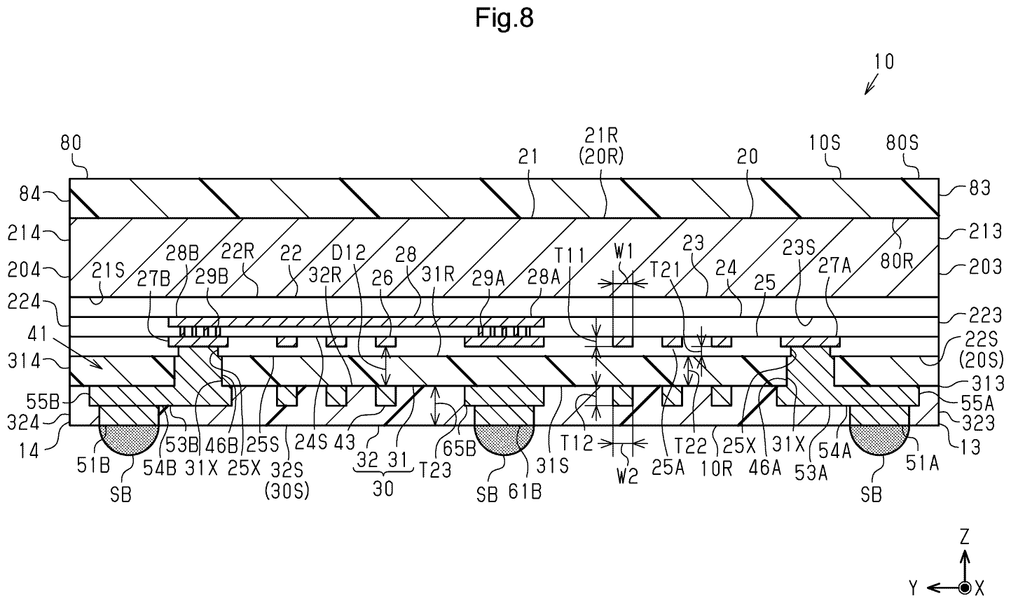

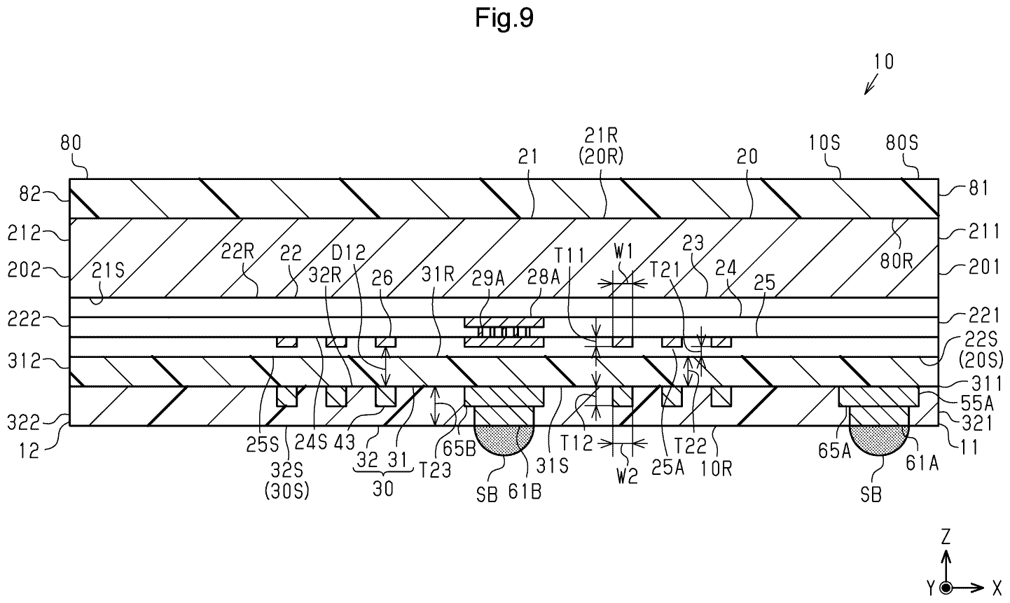

FIGS. 3 and 4 are perspective views showing the exterior of the semiconductor device 10. FIG. 3 is an upper perspective view of the semiconductor device 10, and FIG. 4 is a lower perspective view of the semiconductor device 10. FIG. 5 is a plan view showing the lower side of the semiconductor device 10. In FIG. 5, an encapsulation resin 80 and an element insulation layer 22 are shown transparently. FIG. 6 is a plan view of the semiconductor element 10. In FIG. 6, the element insulation layer 22 is shown transparently. FIG. 7 is a plan view of a conductor 40. In FIG. 7, the encapsulation resin 80 is shown transparently. FIG. 8 is a schematic cross-sectional view of the semiconductor device 10 taken along line 8-8 in FIG. 5. FIG. 9 is a schematic cross-sectional view of the semiconductor device 10 taken along line 9-9 in FIG. 5. For the sake of convenience, FIGS. 8 and 9 may show a member that is not present on the line indicating the cross-sectional position. Further, the position and size of a member may differ from those shown in FIGS. 5 to 7.

### General Structure of Semiconductor Device

As shown in FIGS. 3 and 4, the semiconductor device 10 is, for example, rectangular-box-shaped. In the description hereafter, the thickness-wise direction of the semiconductor device 10 is referred to as a z-direction. A direction orthogonal to the z-direction is referred to as an x-direction. A direction orthogonal to the z-direction and the x-direction is referred to as a y-direction. A view of an object taken in the z-direction is referred to as a plan view.

The semiconductor device 10 includes a device upper surface 10S, a device lower surface 10R, and device side surfaces 11, 12, 13, and 14. The device upper surface 10S and the device lower surface 10R face in opposite directions in the z-direction. The device side surfaces 11, 12, 13, and 14 each intersect the device upper surface 10S and the device lower surface 10R. The device side surfaces 11 and 12 face in opposite directions in the x-direction. The device side surfaces 13 and 14 face in opposite directions in the y-direction.

The semiconductor device 10 includes an external connection member SB. The external connection member SB is disposed on the device lower surface 10R. In an example, the external connection member SB is a solder ball formed of solder. The semiconductor device 10 is mounted on the substrate 920, which is shown in FIG. 2, via the external connection member SB.

As shown in FIGS. 3 to 9, the semiconductor device 10 includes the semiconductor element 20, a surface resin layer 30, a conductor 40, and the encapsulation resin 80. The semiconductor element 20 includes a first coil 26. The conductor 40 includes a second coil 43 and external connection terminals 51A, 51B, 61A, and 61B. The first coil 26 and the second coil 43 correspond to the coils 913A and 913B shown in FIG. 1. The semiconductor element 20 is mounted on the conductor 40. The first coil 26 of the semiconductor element 20 is opposed to the second coil 43 of the conductor 40 in the z-direction. As shown in FIG. 4, the external connection terminals 51A, 51B, 61A, and 61B are exposed from a surface 30S of the surface resin layer 30.

### Semiconductor Element

As shown in FIGS. 6, 8, and 9, the semiconductor element 20 includes an element front surface 20S, an element back surface 20R, and element side surfaces 201, 202, 203, and 204. The element front surface 20S corresponds to a “first element surface.” The element back surface 20R corresponds to a “second element surface.” The element front surface 20S and the element back surface 20R face in opposite directions in the z-direction. The element front surface 20S faces in the same direction as a resin back surface 80R. The semiconductor element 20 is arranged so that the element front surface 20S faces in the same direction as a resin lower surface. The element side surfaces 201, 202, 203, and 204 each intersect the element front surface 20S and the element back surface 20R. In an example, the element side surfaces 201, 202, 203, and 204 are orthogonal to the element front surface 20S and the element back surface 20R. The element side surfaces 201 and 202 face in opposite directions in the x-direction. The element side surfaces 203 and 204 face in opposite directions in the y-direction.

As shown in FIGS. 8 and 9, the semiconductor element 20 includes an element substrate 21.

The element substrate 21 is a semiconductor substrate and is formed from a material including, for example, silicon (Si). In the present embodiment, the element substrate 21 is a Si substrate.

The element substrate 21 includes a substrate front surface 21S, a substrate back surface 21R, and substrate side surfaces 211, 212, 213, and 214. The substrate front surface 21S and the substrate back surface 21R face in opposite directions in the z-direction. As shown in FIGS. 3 and 4, the substrate side surfaces 211 and 212 face in opposite directions in the x-direction. The substrate side surfaces 213 and 214 face in opposite directions in the y-direction. The substrate front surface 21S corresponds to a “first substrate surface.” The substrate back surface 21R corresponds to a “second substrate surface.”

The element insulation layer 22 covers the substrate front surface 21S. The element insulation layer 22 includes an insulation front surface 22S, an insulation back surface 22R, and insulation side surfaces 221, 222, 223, and 224. The insulation front surface 22S of the element insulation layer 22 and the substrate front surface 21S face in the same direction. The insulation back surface 22R of the element insulation layer 22 and the insulation front surface 22S of the element insulation layer 22 face in opposite directions. The insulation back surface 22R of the element insulation layer 22 faces the substrate front surface 21S and is in contact with the substrate front surface 21S. The insulation side surfaces 221, 222, 223, and 224 of the element insulation layer 22 and the element side surfaces 201, 202, 203, and 204 face in the same direction, respectively.

The insulation front surface 22S of the element insulation layer 22 defines the element front surface 20S of the semiconductor element 20. The substrate back surface 21R of the element substrate 21 defines the element back surface 20R of the semiconductor element 20. The substrate side surfaces 211 to 214 of the element substrate 21 and the insulation side surfaces 221 to 224 of the element insulation layer 22 define the element side surfaces 201 to 204 of the semiconductor element 20.

The semiconductor element 20 includes a first coil 26. The first coil 26 corresponds to a “first conductor.” The first coil 26 is spiral in plan view. The first coil 26 includes a first end 26A located outward and a second end 26B located inward. The first end 26A corresponds to an “outer end.” The second end 26B corresponds to an “inner end.”

The first coil 26 is disposed in the element insulation layer 22. In an example, the element insulation layer 22 includes three insulation layers 23, 24, and 25. The insulation layers 23, 24, and 25 are stacked on the substrate front surface 21S of the element substrate 21 in the order of the insulation layers 23, 24, and 25. The first coil 26 is formed on a front surface 24S of the second insulation layer 24. The first coil 26 and the front surface 24S of the second insulation layer 24 are covered by the third insulation layer 25.

The element insulation layer 22 is insulating. The first insulation layer 23, the second insulation layer 24, and the third insulation layer 25 are formed from a material including, for example, silicon (Si). The first insulation layer 23, the second insulation layer 24, and the third insulation layer 25 are formed from, for example, silicon oxide (SiO₂) or silicon nitride (SiN). The material forming first insulation layer 23, the second insulation layer 24, and the third insulation layer 25 may be changed. For example, the first insulation layer 23, the second insulation layer 24, and the third insulation layer 25 may be formed from an insulating resin such as a polyimide resin, a phenol resin, or an epoxy resin.

The semiconductor element 20 includes connection pads 27A and 27B. The connection pads 27A and 27B correspond to an “element pad.” The connection pads 27A and 27B and the first coil 26 are located at the same position in the z-direction. The connection pads 27A and 27B are arranged on the front surface 24S of the second insulation layer 24. The third insulation layer 25 covers the surroundings of the connection pads 27A and 27B. The third insulation layer 25 includes openings 25X partially exposing the connection pads 27A and 27B. The insulation layers 23 and 24 correspond to a “first insulation film.” The insulation layer 25 corresponds to a “second insulation film.”

As shown in FIG. 6, the connection pad 27A is electrically connected to the first end 26A of the first coil 26. The connection pad 27B is electrically connected to the second end 26B of the first coil 26 by an element interconnect 28. The element interconnect 28 corresponds to a “first wiring layer.” Thus, the first coil 26 is connected between the connection pad 27A and the connection pad 27B.

As shown in FIG. 8, the element interconnect 28 is formed on a front surface 23S of the first insulation layer 23. The element interconnect 28 is formed from a material including, for example, Cu or aluminum (Al). The element interconnect 28 includes a first end 28A electrically connected to the first coil 26 by a via 29A. The element interconnect 28 include a second end 28B electrically connected to the connection pad 27B by a via 29B. The vias 29A and 29B extend through the second insulation layer 24. The vias 29A and 29B are formed from a material including Cu, Al, or tungsten (W).

### Surface Resin Layer

The surface resin layer 30 is disposed on the insulation front surface 22S of the element insulation layer 22. The element insulation layer 22 includes the first insulation layer 23, the second insulation layer 24, and the third insulation layer 25. The surface resin layer 30 is disposed on a front surface 25S of the third insulation layer 25.

The surface resin layer 30 includes a first resin portion 31 and a second resin portion 32. The first resin portion 31 is disposed on the insulation front surface 22S of the element insulation layer 22. The first resin portion 31 is in contact with the insulation front surface 22S of the element insulation layer 22.

The first resin portion 31 includes a first resin front surface 31S facing in the z-direction and a first resin back surface 31R facing opposite from the first resin front surface 31S. The first resin front surface 31S corresponds to a “first resin surface.” The first resin back surface 31R of the first resin portion 31 is in contact with the insulation front surface 22S of the element insulation layer 22. The first resin portion 31 includes first resin side surfaces 311, 312, 313, and 314. The first resin side surfaces 311 to 314 each intersect the first resin front surface 31S and the first resin back surface 31R. In an example, the first resin side surfaces 311 to 314 are orthogonal to the first resin front surface 31S and the first resin back surface 31R. The first resin side surfaces 311 and 312 face in opposite directions in the x-direction. The first resin side surfaces 313 and 314 face in opposite directions in the y-direction.

The second resin portion 32 includes a second resin front surface 32S facing in the z-direction and a second resin back surface 32R facing opposite from the second resin front surface 32S. The second resin front surface 32S corresponds to a “second resin surface.” The second resin back surface 32R of the second resin portion 32 is in contact with the first resin front surface 31S of the first resin portion 31. The second resin portion 32 includes second resin side surfaces 321, 322, 323, and 324. The second resin side surfaces 321 to 324 intersects the second resin front surface 32S and the second resin back surface 32R. In an example, the second resin side surfaces 321 to 324 are orthogonal to the second resin front surface 32S and the second resin back surface 32R. The second resin side surfaces 321 and 322 face in opposite directions in the x-direction. The second resin side surfaces 323 and 324 face in opposite directions in the y-direction.

The first resin portion 31 and the second resin portion 32 may be formed from an insulating resin. The insulating resin includes, for example, a polyimide resin, a phenol resin, and an epoxy resin. The material forming the first resin portion 31 may differ from the material forming the second resin portion 32. The material forming the first resin portion 31 may differ in breakdown voltage from the material forming the second resin portion 32. In an example, the first resin portion 31 may be formed of a material having a higher breakdown voltage than a material forming the second resin portion 32. The material forming the first resin portion 31 may differ in adhesion from the material forming the second resin portion 32. In an example, the first resin portion 31 may be formed of a material having a higher adhesion than a material forming the second resin portion 32.

As viewed in the z-direction, the first resin portion 31 and the second resin portion 32 are identical in size to the element substrate 21 and the element insulation layer 22. Thus, the first resin side surface 311 of the first resin portion 31, the second resin side surface 321 of the second resin portion 32, the insulation side surface 221 of the element insulation layer 22, and the substrate side surface 211 of the element substrate 21 are located at the same position in the x-direction, that is, are flush with each other. In the same manner, the first resin side surface 312 of the first resin portion 31, the second resin side surface 322 of the second resin portion 32, the insulation side surface 222 of the element insulation layer 22, and the substrate side surface 212 of the element substrate 21 are located at the same position in the x-direction, that is, are flush with each other. The first resin side surface 313 of the first resin portion 31, the second resin side surface 323 of the second resin portion 32, the insulation side surface 223 of the element insulation layer 22, and the substrate side surface 213 of the element substrate 21 are located at the same position in the y-direction, that is, are flush with each other. The first resin side surface 314 of the first resin portion 31, the second resin side surface 324 of the second resin portion 32, the insulation side surface 224 of the element insulation layer 22, and the substrate side surface 214 of the element substrate 21 are located at the same position in the y-direction, that is, are flush with each other.

At least one of the element side surfaces 201 to 204 of the semiconductor element 20 is exposed without being covered by the first resin portion 31 and the second resin portion 32. In an example, each of the element side surfaces 201 to 204 is exposed from the first resin portion 31 and the second resin portion 32.

The first resin portion 31 has a thickness T22. The second resin portion 32 has a thickness T23. The thickness T22 is larger than the thickness T23. The thickness T22 of the first resin portion 31 may be equal to the thickness T23 of the second resin portion 32. The thickness T22 of the first resin portion 31 may be smaller than the thickness T23 of the second resin portion 32.

### Conductor

As shown in FIGS. 7, 8, and 9, the conductor 40 includes a first wiring member 41, a second wiring member 42, and the second coil 43. The conductor 40 is embedded in the surface resin layer 30.

The first wiring member 41 includes a first external connection terminal 51A, the second external connection terminal 51B, a first pad connector 53A, a second pad connector 53B, a first interconnect 54A, a second interconnect 54B, a first terminal connector 55A, and a second terminal connector 55B.

The second wiring member 42 includes the third external connection terminal 61A, the fourth external connection terminal 61B, a third terminal connector 65A, a fourth terminal connector 65B, and a third interconnect 64. The third terminal connector 65A, the fourth terminal connector 65B, and the third interconnect 64 correspond to a “second lead wire.”

As shown in FIG. 7, the first external connection terminal 51A, the second external connection terminal 51B, the third external connection terminal 61A, and the fourth external connection terminal 61B are each quadrilateral in plan view. The shape of the first external connection terminal 51A, the second external connection terminal 51B, the third external connection terminal 61A, and the fourth external connection terminal 61B may be changed in any manner and may be, for example, circular or polygonal in plan view.

The first external connection terminal 51A, the second external connection terminal 51B, the third external connection terminal 61A, and the fourth external connection terminal 61B may be formed of a material including, for example, Cu. The first external connection terminal 51A, the second external connection terminal 51B, the third external connection terminal 61A, and the fourth external connection terminal 61B may include a conductive layer (plating layer) such as a gold (Au) layer or a nickel (Ni)-palladium (Pd) layer.

As shown in FIGS. 8 and 9, the first pad connector 53A, the second pad connector 53B, the first interconnect 54A, the second interconnect 54B, the first terminal connector 55A, and the second terminal connector 55B are formed on the first resin front surface 31S of the first resin portion 31. The third terminal connector 65A, the fourth terminal connector 65B, and the third interconnect 64 are formed on the first resin front surface 31S of the first resin portion 31.

As shown in FIG. 5, in an example, the first external connection terminal 51A and the second external connection terminal 51B are arranged along the device side surface 12 of the semiconductor device 10. The first external connection terminal 51A and the second external connection terminal 51B may be separated in the y-direction. The first external connection terminal 51A and the second external connection terminal 51B are arranged in the y-direction in plan view. The first external connection terminal 51A is located at a corner formed of the device side surface 12 and the device side surface 13 of the semiconductor device 10. The second external connection terminal 51B is located at the corner of the device side surface 12 and the device side surface 14 of the semiconductor device 10.

As shown in FIGS. 5 and 7, the first pad connector 53A and the second pad connector 53B overlap the connection pads 27A and 27B in the z-direction. The first pad connector 53A and the second pad connector 53B are electrically connected to the connection pads 27A and 27B by through interconnects 46A and 46B. The through interconnects 46A and 46B are disposed in through holes 31X extending through the first resin portion 31.

The first pad connector 53A and the second pad connector 53B are each quadrilateral in plan view. The shape of the first pad connector 53A and the second pad connector 53B may be changed in any manner and may be, for example, circular or polygonal in plan view.

The first pad connector 53A is electrically connected to the first external connection terminal 51A by the first interconnect 54A. The second pad connector 53B is electrically connected to the second external connection terminal 51B by the second interconnect 54B.

The third external connection terminal 61A may be arranged close to the device side surface 11 of the semiconductor device 10. In an example, in plan view, the third external connection terminal 61A is located at the center of the device side surface 11 in the y-direction. The position of the third external connection terminal 61A may be changed in any manner. In an example, the third external connection terminal 61A may be located at a corner formed of the device side surface 11 and the device side surface 13 of the semiconductor device 10 or a corner formed of the device side surface 11 and the device side surface 14.

As shown in FIGS. 4, 5, and 7, the fourth external connection terminal 61B is located in the center of the semiconductor device 10 in plan view. In an example, the third external connection terminal 61A and the fourth external connection terminal 61B are located at the same position in the y-direction. That is, the third external connection terminal 61A and the fourth external connection terminal 61B are arranged in the x-direction.

As shown in FIG. 7, the second coil 43 is spiral in plan view. The second coil 43 includes a first end 43A located outward and a second end 43B located inward. The first end 43A corresponds to an “outer end.” The second end 43B corresponds to an “inner end.” The first end 43A of the second coil 43 is electrically connected to the third external connection terminal 61A by the third interconnect 64. The second end 43B of the second coil 43 is electrically connected to the fourth external connection terminal 61B.

The second coil 43 is disposed on the first resin front surface 31S of the first resin portion 31. The first resin portion 31 covers the insulation front surface 22S of the element insulation layer 22. The first coil 26 is embedded in the element insulation layer 22. The second coil 43 is arranged to overlap the first coil as viewed in the z-direction. Thus, the first coil 26 and the second coil 43 are located at opposite sides of the element insulation layer 22 and the first resin portion 31 and are opposed to each other in the z-direction.

As shown in FIGS. 8 and 9, the first coil 26 has a width W1 in a direction parallel to the element front surface 20S. The width W1 is defined as, for example, the dimension in the y-direction. The second coil 43 has a width W2 in a direction parallel to the element front surface 20S. The width W2 is defined as, for example, the dimension in the y-direction. The width W1 of the first coil 26 corresponds to a “first width-wise dimension.” The width W2 of the second coil 43 corresponds to a “second width-wise dimension.” For example, the width W1 of the first coil 26 is equal to the width W2 of the second coil 43. The width W1 of the first coil 26 may be smaller than the width W2 of the second coil 43. The width W1 of the first coil 26 may be larger than the width W2 of the second coil 43.

A thickness T12 of the second coil 43 in the z-direction is larger than a thickness T11 of the first coil 26. The thickness T11 of the first coil 26 may be equal to the thickness T12 of the second coil 43. The thickness T12 of the second coil 43 may be smaller than the thickness T11 of the first coil 26.

The thickness T22 of the first resin portion 31 is greater than the thickness of the third insulation layer 25 covering the first coil 26 of the semiconductor element 20. More specifically, the thickness T22 of the first resin portion 31 is greater than a thickness T21 of an element resin portion 25A of the third insulation layer 25 from the first coil 26 to the element front surface 20S. The thickness T22 of the first resin portion 31 of the surface resin layer 30 corresponds to the thickness of the first resin portion 31 located between the first coil 26 and the second coil 43. The thickness T21 of the element resin portion 25A of the third insulation layer 25 corresponds to the thickness of the element insulation layer 22 located between the first coil 26 and the second coil 43. The sum of the thickness T22 of the first resin portion 31 and the thickness T21 of the element insulation layer 22 corresponds to a distance D12 between the first coil 26 and the second coil 43 in the z-direction.

As shown in FIGS. 8 and 9, the semiconductor device 10 includes the encapsulation resin 80. The encapsulation resin 80 is arranged on the substrate back surface 21R of the element substrate 21. The encapsulation resin 80 includes a resin front surface 80S, the resin back surface 80R, and resin side surfaces 81, 82, 83, and 84. The resin front surface 80S and the resin back surface 80R face in opposite directions in the z-direction. The resin side surfaces 81 to 84 intersect the resin front surface 80S and the resin back surface 80R. In an example, the resin side surfaces 81 to 84 are orthogonal to the resin front surface 80S and the resin back surface 80R. The resin side surfaces 81 and 82 face in opposite directions in the x-direction. The resin side surfaces 83 and 84 face in opposite directions in the y-direction.

The resin back surface 80R of the encapsulation resin 80 is in contact with the substrate back surface 21R of the element substrate 21. Thus, the encapsulation resin 80 covers the element back surface 20R of the semiconductor element 20. The resin front surface 80S of the encapsulation resin 80 defines a device upper surface 10S of the semiconductor device 10. The element side surfaces 201 to 204 of the semiconductor element 20 is exposed from the encapsulation resin 80.

The semiconductor device 10 is formed in a singulation step.

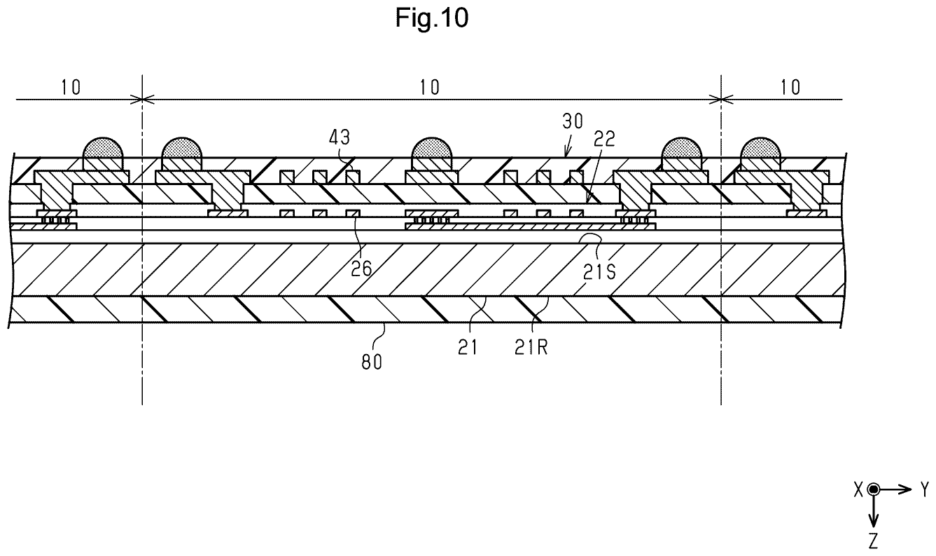

FIG. 10 is schematic cross-sectional view of the semiconductor device 10 that is formed in the singulation step. In FIG. 10, the same reference characters for the components of the semiconductor device 10 are given to members forming the semiconductor device 10.

As shown in FIG. 10, multiple semiconductor devices 10 are formed collectively. A base 21 is a substrate (Si substrate) and is, for example, in the form of a wafer. The base 21 includes a base front surface 21S and a base back surface 21R that face opposite directions in the z-direction. The element insulation layer 22, the surface resin layer 30, the first coil 26, and the second coil 43 are formed on the base front surface 21S. The encapsulation resin 80 is formed on the base back surface 21R. Singulation is performed along single-dashed lines FIG. 10 to form the semiconductor device 10 shown in FIGS. 3 to 9.

### Operation

The semiconductor device 10 includes the semiconductor element 20. The semiconductor element 20 includes the element front surface 20S and the element back surface 20R facing in opposite directions in the z-direction and the element side surfaces 201 to 204 each intersecting the element front surface 20S and the element back surface 20R. The semiconductor element 20 includes the element insulation layer 22 including the insulation front surface 22S defining the element front surface 20S and the first coil 26 disposed in the element insulation layer 22.

The semiconductor device 10 includes the first resin portion 31, the second resin portion 32, and the second coil 43. The first resin portion 31 covers the element front surface 20S of the semiconductor element 20. The first resin portion 31 includes the first resin front surface 31S facing in the same direction as the element front surface 20S of the semiconductor element 20. The second coil 43 is formed on the first resin front surface 31S. The second resin portion 32 includes the second resin front surface 32S facing in the same direction as the first resin front surface 31S and covers the first resin front surface 31S and the second coil 43. The first coil 26 and the second coil 43 are located at opposite sides of the element insulation layer 22 and the first resin portion 31 and are opposed to each other in the z-direction. At least one of the element side surfaces 201 to 204 is exposed without being covered by the first resin portion 31 and the second resin portion 32.

The breakdown voltage of the semiconductor device 10 is determined by the distance D12 between the first coil 26 and the second coil 43 in the z-direction. The element insulation layer 22 and the first resin portion 31 of the surface resin layer 30 are located between the first coil 26 and the second coil 43. This increases the thickness of the element insulation layer 22 and the first resin portion 31 located between the first coil 26 and the second coil 43, thereby improving the breakdown voltage of the semiconductor device 10.

In the semiconductor device 10, at least one of the element side surfaces 201 to 204 is exposed without being covered by the first resin portion 31 and the second resin portion 32. Thus, the semiconductor device 10 is reduced in size as compared to a semiconductor device in which the element side surfaces 201 to 204 are covered by an encapsulation resin.

### Advantages

As described above, the present embodiment has the following advantages.

(1) The semiconductor device 10 includes the semiconductor element 20. The semiconductor element 20 includes the element front surface 20S and the element back surface 20R facing in opposite directions in the z-direction and the element side surfaces 201 to 204 each intersecting the element front surface 20S and the element back surface 20R. The semiconductor element 20 includes the element insulation layer 22 including the insulation front surface 22S defining the element front surface 20S and the first coil 26 disposed in the element insulation layer 22. The semiconductor device 10 includes the first resin portion 31, the second resin portion 32, and the second coil 43. The first resin portion 31 covers the element front surface 20S of the semiconductor element 20. The first resin portion 31 includes the first resin front surface 31S facing in the same direction as the element front surface 20S of the semiconductor element 20. The second coil 43 is formed on the first resin front surface 31S. The second resin portion 32 includes the second resin front surface 32S facing in the same direction as the first resin front surface 31S and covers the first resin front surface 31S and the second coil 43. The first coil 26 and the second coil 43 are located at opposite sides of the element insulation layer 22 and the first resin portion 31 and are opposed to each other in the z-direction. At least one of the element side surfaces 201 to 204 is exposed without being covered by the first resin portion 31 and the second resin portion 32.

The breakdown voltage of the semiconductor device 10 is determined by the distance D12 between the first coil 26 and the second coil 43 in the z-direction. The element insulation layer 22 and the first resin portion 31 of the surface resin layer 30 are located between the first coil 26 and the second coil 43. This increases the thickness of the element insulation layer 22 and the first resin portion 31 located between the first coil 26 and the second coil 43, thereby improving the breakdown voltage of the semiconductor device 10.

(2) In the semiconductor device 10, at least one of the element side surfaces 201 to 204 is exposed without being covered by the first resin portion 31 and the second resin portion 32. Thus, the semiconductor device 10 is reduced in size as compared to a semiconductor device in which the element side surfaces 201 to 204 are covered by an encapsulation resin.

### Modified Examples

The embodiments may be modified, for example, as follows. The above embodiment and the modified examples described below may be combined as long as there is no technical contradiction. In the following modified examples, the same reference characters are given to those components that are the same as the corresponding components of the above embodiments. Such components will not be described in detail.

The positions of the external connection terminals 51A, 51B, 61A, and 61B may be changed.

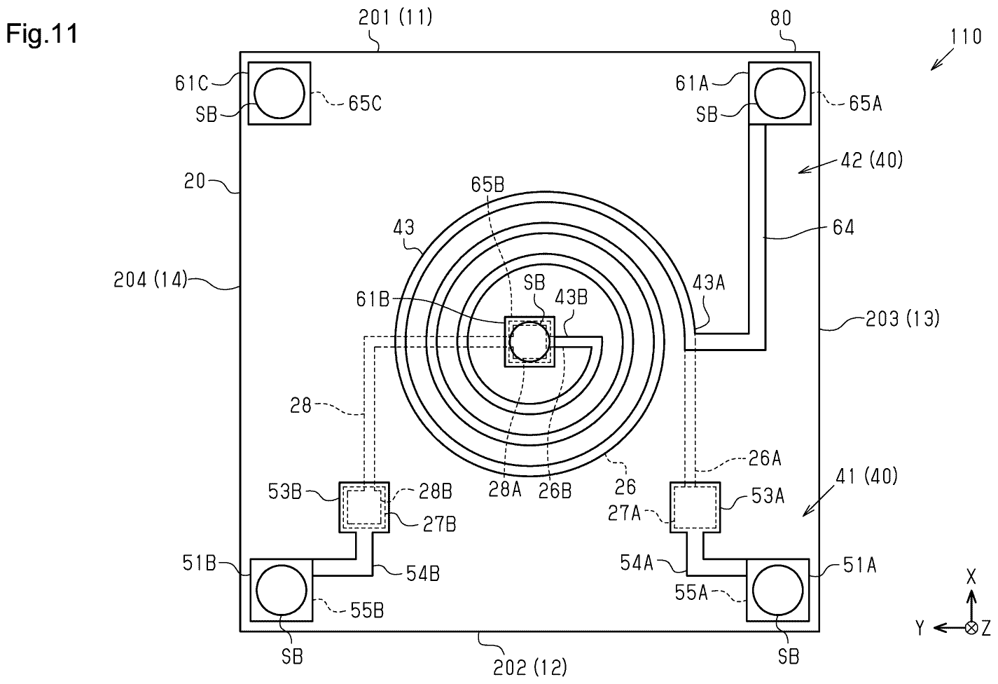

FIG. 11 is a schematic plan view showing a modified example of a semiconductor device 110. The semiconductor device 110 differs from the semiconductor device 10 in the position of the third external connection terminal 61A. The third external connection terminal 61A is located at the corner of the device side surface 11 and the device side surface 13 of the semiconductor device 110. In addition, it is preferred that a dummy terminal connector 65C and a dummy external connection terminal 61C are located at the corner of the device side surface 11 and the device side surface 14 of the semiconductor device 110. The dummy terminal connector 65C and the dummy external connection terminal 61C limit the tilting of the semiconductor device 110, for example, when the semiconductor device 110 is mounted on the substrate 920 shown in FIG. 2.

The surface resin layer 30 may include three or more resin portions.

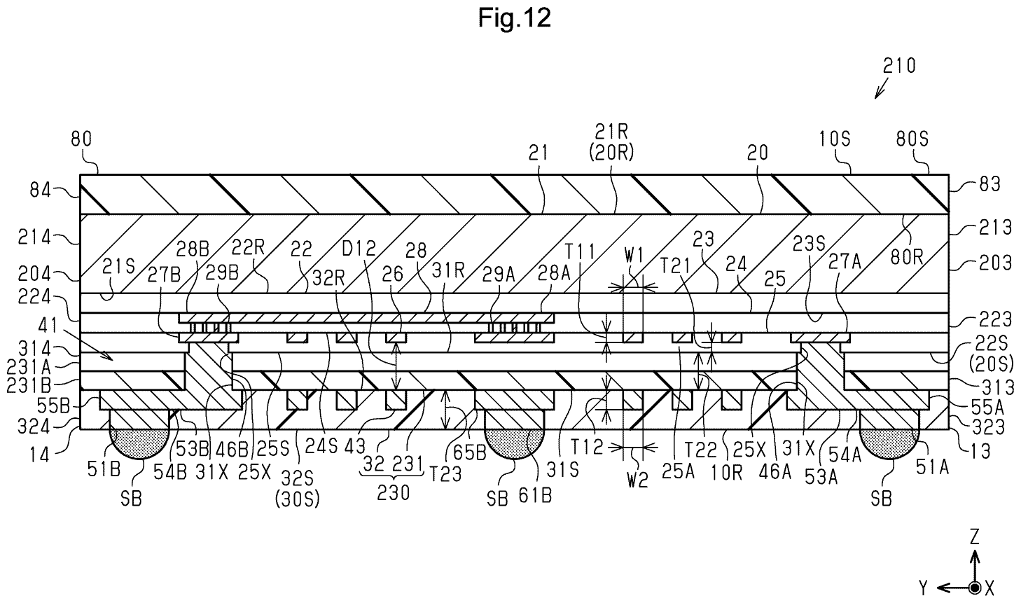

As shown in FIG. 12, the semiconductor device 210 includes a surface resin layer 230. The surface resin layer 230 includes a first resin portion 231 and the second resin portion 32. The first resin portion 231 may include a first resin layer 231A and a second resin layer 231B. The first resin layer 231A and the second resin layer 231B may be formed of the same material. The first resin layer 231A and the second resin layer 231B may be formed of different materials.

The transformer 913 shown in FIG. 1 may be changed to a semiconductor element capacitor chip that uses a capacitor to insulate the first circuit 911 and the second circuit 912. The capacitor chip including a capacitor is an example of a semiconductor device having an insolation configuration.

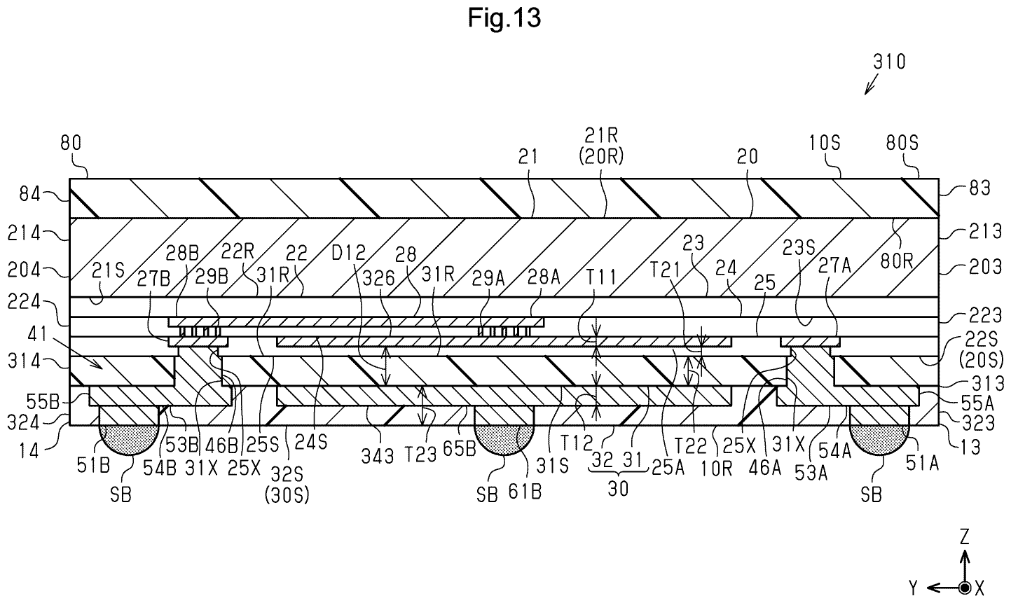

As shown in FIG. 13, a semiconductor device 310 includes a first electrode plate 326 and a second electrode plate 343. The first electrode plate 326 corresponds to a “first conductor.” The second electrode plate 343 corresponds to a “second conductor.”

The first electrode plate 326 is embedded in the element insulation layer 22. The element insulation layer 22 includes the first insulation layer 23, the second insulation layer 24, and the third insulation layer 25. The first electrode plate 326 is disposed on the surface 24S of the second insulation layer 24 of the element insulation layer 22. The first electrode plate 326 and the front surface 24S of the second insulation layer 24 are covered by the third insulation layer 25.

The second electrode plate 343 is embedded in the surface resin layer 30. The surface resin layer 30 includes the first resin portion 31 and the second resin portion 32. The second electrode plate 343 is disposed on the first resin front surface 31S of the first resin portion 31. The second electrode plate 343 and the first resin front surface 31S of the first resin portion 31 are covered by the second resin portion 32.

The first electrode plate 326 overlaps the second electrode plate 343 as viewed in the z-direction. The first electrode plate 326 and the second electrode plate 343 are opposed to each other in the z-direction. The first electrode plate 326 and the second electrode plate 343 form a capacitor. In other words, a semiconductor device 310 may be a capacitor chip including a capacitor. The semiconductor device 310 of the modified example obtains the same advantages as those of the semiconductor device 10 described above.

The semiconductor devices described in the embodiments and modified examples use a first coil and a second coil to transmit signals. The semiconductor devices may be used in other application. The semiconductor device may be used in, for example, a DC voltage conversion circuit (DC-DC converter), a digital isolator, or an isolated AD converter circuit.

In the present disclosure, the term “on” includes the meaning of “above” in addition to the meaning of “on” unless otherwise clearly indicated in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may be the vertical direction. Alternatively, the Y-axis direction may be the vertical direction.

### CLAUSES

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

### [Clause 1]

A semiconductor device, including:
a semiconductor element including a first element surface (20S) and a second element surface (20R) facing in opposite directions in a thickness-wise direction, element side surfaces (201 to 204) intersecting with the first element surface (20S) and the second element surface (20R), an element insulation layer (22) including an insulation front surface (22S) defining the first element surface (20S), and a first conductor (26, 326) disposed in the element insulation layer (22);
a first resin portion (31, 231) including a first resin surface (31S) facing in a same direction as the first element surface (20S) and covering the first element surface (20S);
a second conductor (43, 343) formed on the first resin surface (31S); and
a second resin portion (32) including a second resin surface (32S) facing in a same direction as the first resin surface (31S) and covering the first resin surface (31S) and the second conductor (43), where
the first conductor (26, 326) and the second conductor (43, 343) are located at opposite sides of the element insulation layer (22) and the first resin portion (31, 231) and are opposed to each other in the thickness-wise direction, and
at least one of the element side surfaces (201 to 204) is exposed without being covered by the first resin portion (31, 231) and the second resin portion (32).

### [Clause 2]

The semiconductor device according to clause 1, where each of the element side surfaces (201 to 204) is exposed from the first resin portion (31) and the second resin portion (32).

### [Clause 3]

The semiconductor device according to clause 1 or 2, where
the first conductor includes a first coil (26) that is spiral as viewed in the thickness-wise direction, and
the second conductor (43) includes a second coil that is spiral as viewed in the thickness-wise direction.

### [Clause 4]

The semiconductor device according to clause 1 or 2, where
the first conductor includes a first electrode plate (326) extending parallel to the first element surface (20S),
the second conductor includes a second electrode plate (343) extending parallel to the first element surface (20S), and
the first electrode plate (326) and the second electrode plate (343) form a capacitor.

### [Clause 5]

The semiconductor device according to any one of clauses 1 to 4, where the first resin portion (31) is greater in thickness than the second resin portion (32).

### [Clause 6]

The semiconductor device according to any one of clauses 1 to 4, where the first resin portion (31) is smaller in thickness than the second resin portion (32).

### [Clause 7]

The semiconductor device according to any one of clauses 1 to 6, where the first resin portion (31) is formed of a material having a higher breakdown voltage than a material forming the second resin portion (32).

### [Clause 8]

The semiconductor device according to any one of clauses 1 to 7, where the first resin portion (31) is formed of a material having a higher adhesion than a material forming the second resin portion (32).

### [Clause 9]

The semiconductor device according to any one of clauses 1 to 8, where the first resin portion (231) includes multiple resin layers (231A, 231B).

### [Clause 10]

The semiconductor device according to any one of clauses 1 to 9, where
the semiconductor element includes a semiconductor substrate (21) including a first substrate surface (21S) facing in a same direction as the first element surface (20S) and a second substrate surface (21R) defining the second element surface (20R), the element insulation layer (22) being formed on the first substrate surface (21S),
the element insulation layer (22) includes
   a first insulation film (23, 24) formed on the first substrate surface (21S), and
   a second insulation film (25) formed on the first insulation film (23, 24), and
the first conductor (26, 326) is formed on the first insulation film (23, 24) and covered by the second insulation film (25).

### [Clause 11]

The semiconductor device according to clause 10, where the semiconductor element includes a first wiring layer (28) disposed in the first insulation film (23, 24) and electrically connected to the first conductor (26) and an element pad (27A, 27B) exposed from an opening formed in the second insulation film (25) and electrically connected to the first wiring layer (28).

### [Clause 12]

The semiconductor device according to any one of clauses 1 to 11, further including: an encapsulation resin (80) covering the second element surface (20R).

### [Clause 13]

The semiconductor device according to clause 12, where each of the element side surfaces (201 to 204) is exposed from the encapsulation resin (80).

The description above illustrates examples. One skilled in the art may recognize further possible combinations and replacements of the components and methods (manufacturing processes) in addition to those listed for purposes of describing the techniques of the present disclosure. The present disclosure is intended to include any substitute, modification, changes included in the scope of the disclosure including the claims.

What is claimed is:

1. A semiconductor device, comprising:
a semiconductor element including a first element surface and a second element surface facing in opposite directions in a thickness-wise direction, element side surfaces intersecting with the first element surface and the second element surface, an element insulation layer including an insulation front surface defining the first element surface, and a first conductor disposed in the element insulation layer;
a first resin portion including a first resin surface facing in a same direction as the first element surface and covering the first element surface;
a second conductor formed on the first resin surface; and
a second resin portion including a second resin surface facing in a same direction as the first resin surface and covering the first resin surface and the second conductor, wherein
the first conductor and the second conductor are located at opposite sides of the element insulation layer and the first resin portion and are opposed to each other in the thickness-wise direction, and
at least one of the element side surfaces is exposed without being covered by the first resin portion and the second resin portion.

2. The semiconductor device according to claim 1, wherein each of the element side surfaces is exposed from the first resin portion and the second resin portion.

3. The semiconductor device according to claim 1, wherein
the first conductor includes a first coil that is spiral as viewed in the thickness-wise direction, and
the second conductor includes a second coil that is spiral as viewed in the thickness-wise direction.

4. The semiconductor device according to claim 1, wherein
the first conductor includes a first electrode plate extending parallel to the first element surface,
the second conductor includes a second electrode plate extending parallel to the first element surface, and
the first electrode plate and the second electrode plate form a capacitor.

5. The semiconductor device according to claim 1, wherein the first resin portion is greater in thickness than the second resin portion.

6. The semiconductor device according to claim 1, wherein the first resin portion is smaller in thickness than the second resin portion.

7. The semiconductor device according to claim 1, wherein the first resin portion is formed of a material having a higher breakdown voltage than a material forming the second resin portion.

8. The semiconductor device according to claim 1, wherein the first resin portion is formed of a material having a higher adhesion than a material forming the second resin portion.

9. The semiconductor device according to claim 1, wherein the first resin portion includes multiple resin layers.

10. The semiconductor device according to claim 1, wherein
the semiconductor element includes a semiconductor substrate including a first substrate surface facing in a same direction as the first element surface and a second substrate surface defining the second element surface, the element insulation layer being formed on the first substrate surface,
the element insulation layer includes
a first insulation film formed on the first substrate surface, and
a second insulation film formed on the first insulation film, and
the first conductor is formed on the first insulation film and covered by the second insulation film.

11. The semiconductor device according to claim 10, wherein the semiconductor element includes a first wiring layer disposed in the first insulation film and electrically connected to the first conductor and an element pad exposed from an opening formed in the second insulation film and electrically connected to the first wiring layer.

12. The semiconductor device according to claim 1, further comprising:
an encapsulation resin covering the second element surface.

13. The semiconductor device according to claim 12, wherein each of the element side surfaces is exposed from the encapsulation resin.
